(19) United States
(12) Patent Application Publication
(10) Pub. No.: US 2025/0041977 A1
(43) Pub. Date: Feb. 6, 2025

(54) SOLDER MATERIAL

(71) Applicant: FUJI ELECTRIC CO., LTD., Kawasaki-shi (JP)

(72) Inventors: Kohei MITSUI, Tokyo (JP); Hirohiko WATANABE, Tokyo (JP); Shunsuke SAITO, Tokyo (JP); Fumihiko MOMOSE, Higashi-chikuma-gun (JP)

(73) Assignee: FUJI ELECTRIC CO., LTD., Kawasaki-shi (JP)

(21) Appl. No.: 18/922,811

(22) Filed: Oct. 22, 2024

Related U.S. Application Data
(63) Continuation of application No. PCT/JP2023/036193, filed on Oct. 4, 2023.

(30) Foreign Application Priority Data
Nov. 7, 2022 (JP) 2022-178189

(51) Int. Cl. B23K 35/26; B23K 101/40; C22C 13/00; H01L 23/00

(52) U.S. Cl. CPC B23K 35/262; C22C 13/00; H01L 24/29; H01L 24/32; B23K 2101/40; H01L 2224/29023; H01L 2224/29111; H01L 2224/2912; H01L 2224/29139; H01L 2224/29147; H01L 2224/29155; H01L 2224/32227; H01L 2924/35121

(57) ABSTRACT

Solder material with excellent elongation at break in high-temperature environments. Provided are: a solder material containing 5.0% by mass or more and 10.0% by mass or less of Sb, 2.0% by mass or more and 6.0% by mass or less of Ag, 0.1% by mass or more and 0.5% by mass or less of Ni, 3.0% by mass or more and 8.0% by mass or less of Cu, and the remainder consisting of Sn and inevitable impurities; a solder bonding portion including a bonding layer in which the solder material is melted; and a semiconductor device including the bonding portion.

### TECHNICAL FIELD

The present invention relates to a solder material. In particular, the present invention relates to a solder material with improved elongation at break in high-temperature environments, that is, a solder suitable for bonding a semiconductor element.

### BACKGROUND ART

Power semiconductor modules are widely used in fields in which efficient power conversion is required. Their application domain is expanding in the power electronics field, such as for industrial equipment, electric vehicles, and home appliances. These power semiconductor modules contain switching elements and diodes, and Si (silicon) or SiC (silicon carbide) semiconductor elements are used. The semiconductor element is bonded to a laminate substrate with a bonding material, and solder materials have been used as the bonding material.

In recent years, Pb-free solders containing no lead components have been adopted as an alternative to Sn—Pb-based solders due to environmental issues. Among the currently known Pb-free solders of various compositions, an Sn—Ag-based Pb-free solder is often used as a solder material applied to power semiconductor modules such as IGBT modules, as it has a relatively good balance in terms of solder wettability, mechanical properties, thermal resistance, and the like, and has actually been used in products.

Solder compositions are known, which include 0.01% by weight or more and 0.5% by weight or less of Ni, more than 2% by weight and 5% by weight or less of Cu, and the remainder Sn, and may further contain at least one selected from the group consisting of Ag, In, Zn, Sb, Ge, and P (see, for example, Patent Document 1). The solder composition disclosed in Patent Document 1 is said to suppress conductor disconnection due to the corrosion of conductors having Cu as the main component and to have properties similar to those of conventional Sn—Pb-based solder compositions.

Solder alloys are known, which have an alloy composition including, in % by mass, Sb: 9.0 to 33.0%, Ag: more than 4.0% and less than 11.0%, Cu: more than 2.0% and less than 6.0%, and the remainder Sn (see, for example, Patent Document 2). The solder alloy disclosed in Patent Document 2 is said to suppress chip cracking during cooling, improve heat dissipation properties of the solder joint, and exhibit a high degree of bonding strength at high temperatures.

### REFERENCE DOCUMENT LIST

### Patent Literatures

Patent Document 1: JP 2005-324257 A
Patent Document 2: WO 2020/122253

### SUMMARY OF INVENTION

### Problem to be Solved by the Invention

Due to the recent increase in current in power semiconductor modules and their operation in high-temperature environments, the generation of cracks in the solder bonding portion between the semiconductor element and the laminate substrate has become a problem. This cracking is believed to be caused by thermal stress. When cracks occur in the solder bonding portion, the electrical resistance increases, which causes a further temperature rise. Although attempts have been made to improve the strength, Young's modulus, and the like of solder materials at room temperature, they are inadequate for use in high-temperature environments.

### Means for Solving the Problems

The present inventors have made extensive studies to find that improving the creep properties and elongation at break at high temperatures of about 175° C. improves the reliability of a solder bonding portion. Specifically, the present inventors concluded that by adding a predetermined amount of Cu to a solder material containing Sn, Sb, Ag, and Ni, the creep properties and elongation at break are improved at high temperatures while maintaining the same Young's modulus, and the reliability of the module is improved, thereby achieving the present invention.

According to one embodiment, the present invention relates to a solder material containing 5.0% by mass or more and 10.0% by mass or less of Sb, 2.0% by mass or more and 6.0% by mass or less of Ag, 0.1% by mass or more and 0.5% by mass or less of Ni, 3.0% by mass or more and 8.0% by mass or less of Cu, and the remainder consisting of Sn and inevitable impurities.

In the solder material, it is preferable that Cu be contained in an amount of 4.5% by mass or more and 8.0% by mass or less.

In any of the aforementioned solder materials, it is preferable that Sb be contained in an amount of 6.0% by mass or more and 8.5% by mass or less.

In any of the aforementioned solder materials, it is preferable that Ag be contained in an amount of 3.0% by mass or more and 6.0% by mass or less.

It is preferable that any of the aforementioned solder materials be a solder material used for bonding a semiconductor element.

According to another embodiment, the present invention relates to a solder bonding portion, including a solder bonding layer in which any of the aforementioned solder materials is melted, and a member to be bonded including a metal layer on a surface in contact with the solder bonding layer.

According to another embodiment, the present invention relates to a semiconductor device, including a semiconductor element bonded on a laminate substrate, and a conductive connecting member bonded to the semiconductor element, wherein the device includes the aforementioned solder bonding portion between the laminate substrate and the semiconductor element or between the semiconductor element and the conductive connecting member.

According to yet another embodiment, the present invention relates to a semiconductor device, including a semiconductor element bonded on a laminate substrate, and a cooling system bonded to the opposite side of the laminate substrate from the side to which the semiconductor element is bonded, wherein the device includes the aforementioned solder bonding portion between the laminate substrate and the cooling system.

### Effects of Invention

The present invention can provide a solder material with improved elongation at break and creep rupture elongation at high temperatures, excellent stress relaxation, and high wettability. This allows suitable use of the solder material for bonding semiconductor elements even in semiconductor devices that are used in high-temperature environments and generate large currents of up to several thousand amperes, thereby suppressing cracking in the bonding portion and contributing to improved reliability of the semiconductor device. Hereinafter, elongation at break and creep rupture elongation may be referred to as “elongation properties” in the present specification.

### BRIEF DESCRIPTION OF DRAWINGS

FIG. 1 is a conceptual cross-sectional view of the cross-sectional structure of the semiconductor device according to one embodiment of the present invention.

FIG. 2A is a diagram showing the shape of the test piece used in the Examples.

FIG. 2B is a cross-sectional view of FIG. 2A at the X-X line.

FIG. 3 is a graph showing a relationship between the content of Cu in the solder material and normalized elongation at break.

FIG. 4 is a graph showing a relationship between the content of Cu in the solder material and normalized creep rupture elongation.

### MODE FOR CARRYING OUT THE INVENTION

Embodiments of the present invention will be described below with reference to attached drawings. However, the present invention is not limited by the embodiments described below.

### First Embodiment: Solder Material

According to a first embodiment, the present invention is a solder material, which is an alloy containing 5.0% by mass or more and 10.0% by mass or less of Sb, 2.0% by mass or more and 6.0% by mass or less of Ag, 0.1% by mass or more and 0.5% by mass or less of Ni, 3.0% by mass or more and 8.0% by mass or less of Cu, and the remainder consisting of Sn and inevitable impurities.

In the solder material according to the first embodiment, the inevitable impurities mainly refer to Cu, Ni, Zn, Fe, Al, As, Cd, Au, In, P, Pb, and the like. The upper limit of the content of each element treated as inevitable impurities varies depending on the main components of the solder material and is defined by international standards. For example, the upper limit of the amount of inevitable impurities in the solder material according to the present embodiment may be the value defined by the international standards for Sn—Ag-based solders and Sn—Sb-based solders. The solder material according to the first embodiment is a Pb-free solder alloy that does not contain lead.

The content of Sb is 5.0% by mass or more and 10.0% by mass or less. By containing Sb in this range, the Sn phase is strengthened by solid solution strengthening, forming an Sn—Sb phase, which improves the elongation properties (creep properties) without breaking. Cracks and peeling are thus less likely to occur at the solder bonding portion, which is preferable. When the content of Sb is less than 5.0% by mass, the solid solution strengthening of the Sn layer by Sb is insufficient, and deformation of Sn is induced, which is disadvantageous in that it degrades the creep properties. When the content of Sb exceeds 10.0% by mass, the compound of Sn and Sb, SbSn, may coarsen, which is disadvantageous in that this results in stress concentration, causing rupture and reducing the creep properties. The content of Sb is more preferably 5.5% by mass or more and 8.5% by mass or less, 5.5% by mass or more and 7.0% by mass or less, or 6.0% by mass or more and 8.5% by mass or less. The composition range described above allows the Sn—Sb phase to approach a peritectic composition, improve wettability, and maximize the solid solution strengthening by Sb addition, and is also preferable in terms of void reduction and creep properties. The content of Sb is more preferably 6.0% by mass or more and 7.0% by mass or less. This is because the peritectic composition is in this range.

The content of Ag is 2.0% by mass or more and 6.0% by mass or less. Containing Ag in this range allows to maintain the pinning effect on dislocation motion even at temperatures as high as 175° C., and to have excellent wettability. This thus gives an advantage of low initial void fraction and easily ensured bonding quality. When the content of Ag is less than 2.0% by mass, the dispersion of the Ag₃Sn phase is small, which is disadvantageous in that local deformation is more easily induced during deformation in a high-temperature environment of 175° C., and when it exceeds 6.0% by mass, there may be disadvantages such as reduced wettability and increased melting point. The content of Ag is more preferably 3.0% by mass or more and 6.0% by mass or less. Containing Ag in this range allows the Sn—Ag phase to approach a eutectic composition, which improves wettability. It is also preferable in terms of bondability and creep properties, as the fine Sn—Ag phase is uniformly dispersed around the Sn phase. Furthermore, it is also preferable in terms of production as it can have uniform properties. The content of Ag is more preferably 3.5% by mass or more and 5.0% by mass or less. Containing Ag in this range allows the Sn—Ag phase to further approach a eutectic composition, which is still more preferable in terms of creep properties and production as described above. The content of Ag is even more preferably 3.7% by mass or more and 5.0% by mass or less. Since the composition becomes nearly eutectic within said range, it is even more preferable in terms of bondability, creep properties, and production as described above.

The content of Ni is 0.1% by mass or more and 0.5% by mass or less. By containing Ni in this range, particularly when used for Cu bonding applications, the product at the solder/Cu substrate interface changes from Cu₆Sn to (Cu, Ni)₆Sn, which suppresses the degradation of the bonding portion toughness (elongation properties) after high-temperature aging. If the content of Ni, which is expected to improve the strength due to grain refinement and suppress variation in the mechanical properties due to polycrystallization, is less than 0.1% by mass, the above effects may not be sufficiently exhibited, and if it exceeds 0.5% by mass, the melting point may increase. The content of Ni is more preferably 0.15% by mass or more and 0.4% by mass or less. Within this range, the toughness is improved and cracks are less likely to occur. It is also preferable as the amount of initial void formed during large-area bonding is small.

The content of Cu is 3.0% by mass or more and 8.0% by mass or less. Containing Cu in this range allows to confer sliding properties to the solder material. This has the advantage that after stress is applied, slip deformation occurs, improving the creep properties and thus producing stress relaxation. By containing 3.0% by mass or more Cu, the fracture mode changes to grain boundary sliding, which allows to improve the creep properties by at least 40%. When the content of Cu is less than 3.0% by mass, sufficient sliding properties cannot be conferred to the solder material. When the Cu content exceeds 8.0% by mass, a hard CuSn-based structure is believed to be formed in excess, which reduces the creep properties. Moreover, from the viewpoint of wettability, the content of Cu is 8.0% by mass or less.

The content of Cu is preferably 4.5% by mass or more and 8.0% by mass or less. Containing Cu in this range allows to improve the creep properties at high temperatures, particularly at 175° C., more than twofold compared to when Cu is not contained (from the extrapolated line in FIG. 4). In particular, having a Cu content of 5.2% by mass or more and 7.8% by mass or less allows to increase the creep properties by a factor of 2.5 or more (FIG. 4). In addition, having a Cu content of 5.9% by mass or more and 7.0% by mass or less allows to increase the creep properties by a factor of 3.0 or more (FIG. 4). Furthermore, by having a Cu content of 4.8% by mass or more and 5.3% by mass or less, deformation such as burrs and local irregularities are reduced, which makes plastic forming easier when working it into a predetermined shape. That is, the material also has excellent workability as a solder material and high mechanical strength as a bonding layer.

If a Ni-containing layer (plating, etc.) is applied to the portion to be bonded, Cu, which is a component of the solder material, may be consumed in a reaction with the Ni eluted in the solder. The Ni-containing layer refers to a layer containing 50% by mass or more Ni, and may be a base material, or a layer containing Ni or a Ni alloy formed by a film-forming method such as plating. Specifically, for example, it may be a NiP plated layer containing more than 0% by mass of P and 10% by mass or less of P. In addition, when the portion to be bonded is a Cu layer, Sn, which is a component of the solder material, may be consumed in a reaction with the Cu eluted in the solder. Therefore, when used for bonding applications of Ni-containing layers or Cu layers, the content range of Cu in the solder material is preferably, for example, 5.1% by mass or more and 8.0% by mass or less, and preferably 5.2% by mass or more and 7.5% by mass or less. The Cu layer of said portion to be bonded may be any material containing 50% by mass or more Cu, and contains Cu or a Cu alloy.

Adding Bi to the solder material according to the first embodiment having the above composition may not be preferable as a low melting point phase is formed, which reduces the mechanical strength, and as Bi is also easily oxidized. In particular, adding 2% by mass or more Bi is not preferable. In addition, adding Zn makes it more prone to oxidation, which may not be preferable as it deteriorates wettability. In particular, adding 2% by mass or more of Zn is not preferable.

In the present specification, the creep properties of the solder material are defined as the value of strain multiplied by stress required to rupture the solder material, and can also be referred to as strain energy. The strain energy required to rupture the solder material is referred to as the creep rupture elongation. In the present specification, the creep rupture elongation refers to the value of elongation to rupture when a constant load (constant stress) is applied to a test piece at a specific temperature. In the present specification below, the creep rupture elongation refers to the creep rupture elongation at 175° C. unless otherwise specified. The test piece used is a microscopic test piece with a gauge diameter of 1 mm and a gauge length of 2.4 mm, and the constant load is set to 7 N (8.92 MPa). This load is determined so that the test piece is given the deformation rate of the solder bonding layer in the heat cycle test of the semiconductor device to which the solder material according to the present embodiment is applied. Specifically, a strain rate in the range of about 1.0×10⁻⁵ to 5.0×10⁻⁵ (1/s) can be given to obtain a constant load of 7 N. The conditions of the heat cycle test that gives the above deformation rate are: a high temperature of 150° C., a low temperature of −55° C., a retention time of 60 minutes, and a temperature change of 7° C./minute. Evaluating the creep rupture elongation allows to evaluate stress relaxation and fatigue properties, and it is believed that the larger the value of creep rupture elongation, the better the stress relaxation and fatigue properties. In the above measurement method, since the test is performed at a constant load, the creep properties (strain energy) and creep rupture elongation are proportional and can be considered equivalent.

The solder material according to the present invention can be prepared by melting each raw material selected from Sn, Sb, Ag, Ni, and Cu, or a base alloy containing each raw material, in an electric furnace according to a conventional method. Each raw material used preferably has a purity of 99.99% by mass or more.

The solder material according to the above composition can be worked in the form of a plate-like preform material or a solder paste prepared by powdering the material and mixing the powder with a flux. If the material is to be provided in the form of a solder paste prepared by working the material into the form of powder and mixing the powder with a flux, with respect to the particle size (particle diameter) of the powdered solder, the distribution of the particle size is preferably in the range of 10 to 100 μm, and is more preferably in the range of 20 to 50 μm. The average particle size can be, for example, 25 to 50 μm when measured using a general laser diffraction/scattering particle size analyzer. For the flux, any flux can be used, and in particular, a rosin-based flux can be preferably used.

The solder material according to the present embodiment has excellent elongation at break and creep properties at high temperatures of about 175° C. to 200° C., and can be suitably used for bonding members in electronic devices. In particular, the material can be suitably used for bonding the back electrode of a semiconductor element to the electrode of a laminate substrate.

### Second Embodiment: Solder Bonding Portion

According to a second embodiment, the present invention is a solder bonding portion, including a solder bonding layer in which the solder material of the first embodiment is melted, and a member to be bonded including a metal layer on a surface in contact with the solder bonding layer.

The solder bonding layer constituting the solder bonding portion according to the present embodiment may be a layer obtained by melting the solder material of the first embodiment. The thickness and shape of the solder material used to form the solder bonding layer can be appropriately set by those skilled in the art according to the purpose and application, and they are not particularly limited. As an example, 50 μm or more is preferable for bonding the front surface of a semiconductor element and the wiring member of a lead frame or the like, but it is not limited to this range. For bonding the back electrode of a semiconductor element and the conductive plate of a laminate substrate, the thickness of the solder bonding layer can be about 200 to 300 μm, and is preferably about 200 to 250 μm, but it is not limited to this range. For bonding a laminate substrate and a radiator plate, approximately 400 to 500 μm is preferable.

The member to be bonded constituting the solder bonding portion according to the present embodiment is a member having a metal layer on a surface in contact with the solder bonding layer. The type of metal constituting the metal layer is not particularly limited, but in general, the member to be bonded may be a member having an electrode, and the electrode can be composed of Cu, Ni, Al, Ti, Au, Ag or an alloy thereof. The member to be bonded may be a member with a plated film containing these metals on the surface in contact with the solder bonding layer.

The solder bonding portion is formed by placing a solder material of a predetermined shape and thickness in contact with the metal layer of the member to be bonded and heating it at a predetermined temperature. The bonding atmosphere can be a nitrogen atmosphere; alternatively, the bonding can also be carried out in a reactive atmosphere such as hydrogen or formic acid. In particular, when using a plate-like solder, it is preferable to use a gas having a reducing effect such as hydrogen or formic acid. When bonding in these active gas atmospheres having a reducing effect, it is preferable to use a temperature at which the gas effectively reduces an oxide, such as 250 to 300° C. The bonding temperature of the solder plate and solder paste may be the melting point of the solder material (Tm)+(50° C.±10° C.). For the actual bonding, a stable bonding quality can be obtained by ensuring a temperature and time of a certain level or more in order to bond with a temperature distribution of several ° C. or more. The molten solder is then solidified by cooling it at a predetermined rate of temperature decrease to form the solder bonding layer. The rate of temperature rise of this heating treatment can be about 1° C./s, and the rate of temperature decrease is preferably 5° C./s or more, and more preferably 8° C./s or more and 15° C./s or less. Setting the rates of temperature increase and decrease of the heat treatment within these ranges allows formation of finer crystal grains and for each phase to precipitate uniformly, thereby reducing variation in quality.

The solder bonding portion according to the second embodiment may constitute part of an electronic device, which includes, but is not limited to, electrical and power devices such as inverters, mega solar systems, fuel cells, elevators, cooling apparatuses, and in-car semiconductor devices. Typically, electronic devices are semiconductor devices. The bonding portion in a semiconductor device may be a die bonding portion, a bonding portion between a conductive plate and a radiator plate, a bonding portion between terminals, a bonding portion between a terminal and another member, or any other bonding portion; in particular, a bonding portion through which a large current flows, but it is not limited thereto. The semiconductor device will be described in detail in a third embodiment.

The solder bonding portion according to the second embodiment has excellent stress relaxation properties at high temperatures. As a result, the solder bonding portion is less prone to cracking and is highly reliable.

### Third Embodiment: Semiconductor Device

According to a third embodiment, the present invention is a semiconductor device including a semiconductor element bonded on a laminate substrate, and includes a solder bonding layer in which the solder material of the first embodiment is melted. In other words, the semiconductor device according to the third embodiment includes the solder bonding portion according to the second embodiment, in which the member to be bonded is any member constituting a semiconductor element and/or a semiconductor device.

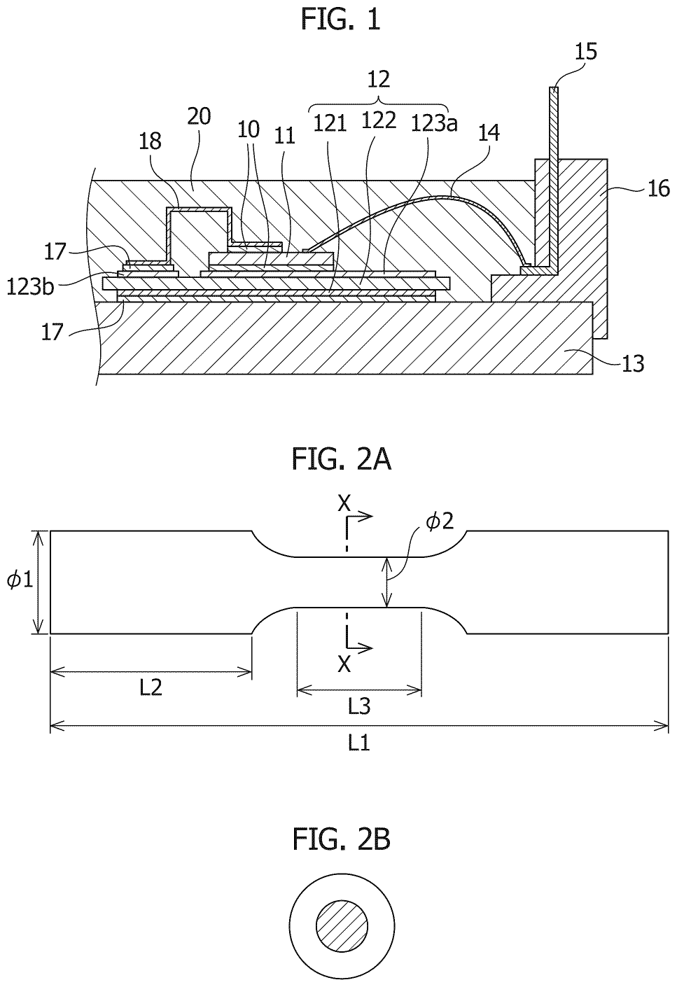

FIG. 1 is a conceptual cross-sectional view of a power semiconductor module, which is an example of the semiconductor device according to the present embodiment. The power semiconductor module illustrated has a laminate structure in which the back electrode of a semiconductor element 11 is bonded to a laminate substrate 12 by a bonding layer 10, and the laminate substrate 12 is bonded to a radiator plate 13 by a bonding layer 17. The radiator plate 13 is attached to a case 16 incorporating an external terminal 15. The front electrode of the semiconductor element 11 and the electrode of the laminate substrate 12 are connected via a lead frame 18, which is a conductive connecting member. In addition, the semiconductor element 11 and the external terminal 15 are connected via an aluminum wire 14. The space constituted by the case 16 and the radiator plate 13 is filled with an encapsulating material 20 in contact with the semiconductor element 11, the laminate substrate 12, the lead frame 18, and the conductive connecting member, the aluminum wire 14. FIG. 1 describes as an example an embodiment including the bonding layer 10 in which the solder material according to the first embodiment is melted, between the back electrode of the semiconductor element 11 and the laminate substrate 12, and between the front electrode of the semiconductor element 11 and the lead frame 18. However, the solder material according to the first embodiment can be used for bonding any part of a semiconductor device, and the present invention is not limited to the illustrated embodiment.

The semiconductor element 11 is a power chip such as an IGBT (insulated gate bipolar transistor) or a diode chip, and may be a Si device, or a wide-gap semiconductor device such as a SiC device, GaN device, diamond device, or ZnO device. In addition, these devices may be used in combination. For example, a hybrid module using Si-IGBT and SiC-SBD or the like can be used. The number of semiconductor elements mounted may be one or more.

The laminate substrate 12 can be composed of an insulating substrate 122, a first conductive plate 121 formed on one main surface thereof, and second conductive plates 123a and 123b formed on the other main surface thereof. As the insulating substrate 122, a material with excellent electrical insulation and thermal conductivity can be used. Examples of the material of the insulating substrate 122 include Al₂O₃, AlN and SiN. For high-voltage applications in particular, a material that provides both electrical insulation and thermal conductivity is preferable, and AlN or SiN can be used, but this is not limited thereto. As the first conductive plate 121 and the second conductive plates 123a and b, a metal material with excellent workability such as Cu and Al can be used. The conductive plate may be made of Cu or Al that has been subjected to a surface treatment such as Ni plating for the purpose of rust prevention and the like, and has a Ni-containing layer that contains Ni or a Ni alloy provided on the surface. Specific examples of the Ni-containing layer obtained by Ni plating include a layer containing NiP and a layer containing NiB, but they are not limited thereto. Examples of the method for disposing the first conductive plate 121 and the second conductive plates 123a and 123b on the insulating substrate 122 include a direct copper bonding method and an active metal brazing method. In the illustrated embodiment, the two second conductive plates 123a and 123b are provided non-continuously on the insulating substrate 122, with one second conductive plate 123a serving as an electrode to be bonded to the semiconductor element 11 and the other second conductive plate 123b as an electrode to be connected to the lead frame 18. However, the number and mode of connection of the first and second conductive plates are not limited to the illustrated embodiment.

The lead frame 18 is a conductive connecting member that connects the semiconductor element 11 to the second conductive plate 123b and the like. Specifically, the lead frame 18 can be bonded to the front electrode of the semiconductor element 11, which is located on the opposite side of the electrode in contact with the laminate substrate 12 (back electrode), for example, with the bonding layer 10 in which the solder material according to the first embodiment is melted. In addition, the lead frame 18 can also be bonded to the wiring portion of the second conductive plate 123b or the like with the bonding layer 17 of the solder material or the like. The lead frame 18 may be of a metal such as copper or an alloy containing copper. As a Ni-containing layer, a Ni or Ni alloy layer (such as NiP alloy or NiB alloy), or a Cr or Cr alloy layer may be formed on the surface of the lead frame 18 by a plating method or the like. In this case, the film thickness of the Ni or Ni alloy layer or the Cr or Cr alloy layer can be about 20 μm or less. The lead frame may be connected to an output terminal (not shown). A wire can also be used as the conductive connecting member that connects the semiconductor element 11 to the second conductive plate 123b or the like. A solder material may not be used when bonding by wire bonding.

For the radiator plate 13, a metal with excellent thermal conductivity such as copper or aluminum is used. To prevent corrosion, the radiator plate 13 can also be coated with Ni or a Ni alloy (such as NiP alloy or NiB alloy) as a Ni-containing layer by a plating method or the like. The radiator plate may be a cooling system having a function such as water cooling or air cooling. There may also be a semiconductor device of a mode in which the case 16 is attached to the laminate substrate 12 and the radiator plate 13 is not attached to the case 16.

The bonding layer 10 which bonds the front electrode of the semiconductor element 11 and the lead frame 18, and the bonding layer 10 which bonds the back electrode of the semiconductor element 11 and the second conductive plate 123a can be formed using the solder material according to the first embodiment. Since the generation of cracks has conventionally been a problem in these bonding portions, using the solder material according to the first embodiment can improve reliability in these bonding layers. The bonding layer 17 between other members such as the second conductive plate 123b and the radiator plate 13 can be formed using the solder material according to the first embodiment, but can also be formed using any Pb-free solder. Examples thereof include Sn—Ag—Cu-based, Sn—Sb-based, Sn—Sb—Ag-based, Sn—Cu-based, Sn—Sb—Ag—Cu-based, Sn—Cu—Ni-based, and Sn—Ag-based solders, but are not limited thereto. Alternatively, a bonding layer can also be formed by using a connecting material containing micrometallic particles, such as sintered nanosilver particles. The disposition of the bonding layer 10 in which the solder material according to the first embodiment is melted and the optional bonding layer 17 in the illustrated semiconductor device is an example. The semiconductor device according to the third embodiment of the present invention may include a bonding layer in which the solder material according to the first embodiment is melted between any members constituting the device. Therefore, the bonding layer between the laminate substrate 12 and the radiator plate 13 may be a bonding layer in which the solder material according to the first embodiment is melted.

The case 16 can be composed of thermoplastic resin such as polyphenylene sulfide (PPS) or polybutylene terephthalate (PBT).

The encapsulating material 20 may be a cured product of a thermosetting resin obtained by curing a thermosetting resin composition that contains a thermosetting resin base and an inorganic filler, and may optionally contain a curing agent, a curing accelerator, and an additive.

The thermosetting resin base is not particularly limited, and examples thereof include an epoxy resin, a phenol resin, a maleimide resin, a cyanate resin, and an oxazine resin. Of these, epoxy resins having at least two or more epoxy groups per molecule are particularly preferable because of their high dimensional stability, water and chemical resistance, and electrical insulation properties. Specifically, aliphatic epoxy resins, alicyclic epoxy resins, or mixtures thereof are preferably used. As an encapsulating resin, a thermosetting resin is preferable due to the requirements of heat resistance and high insulation properties, and in particular, epoxy resins are preferable for their high elasticity.

An aliphatic epoxy resin refers to an epoxy compound in which the carbon to which the epoxy group is directly bound is a carbon constituting an aliphatic hydrocarbon. Therefore, even compounds that contain an aromatic ring in their main backbone are classified as aliphatic epoxy resins if they satisfy the above conditions. Examples of aliphatic epoxy resins include bisphenol A epoxy resin, bisphenol F epoxy resin, bisphenol AD epoxy resin, biphenyl epoxy resin, naphthalene epoxy resin, cresol novolac epoxy resin, and multifunctional epoxy resins with three or more functions but are not limited thereto. These can be used alone, or two or more can be used as a mixture. Naphthalene epoxy resins and multifunctional epoxy resins with three or more functions are also referred to as high heat-resistant epoxy resins because of their high glass transition temperature. Containing these high heat-resistant epoxy resins allows improvement of heat resistance.

An alicyclic epoxy resin refers to an epoxy compound in which the two carbon atoms constituting the epoxy group constitute an alicyclic compound. Examples of alicyclic epoxy resins include monofunctional epoxy resins, bifunctional epoxy resins and multifunctional epoxy resins with three or more functional groups, but are not limited thereto. The alicyclic epoxy resins can also be used alone, or two or more alicyclic epoxy resins can be used as a mixture. When an alicyclic epoxy resin is cured by mixing it with an acid anhydride curing agent, the glass transition temperature increases, and therefore mixing an aliphatic epoxy resin with an alicyclic epoxy resin allows achieving higher heat resistance.

The thermosetting resin base used in the encapsulating material 20 may be a mixture of the above aliphatic epoxy resin and alicyclic epoxy resin. The mixing ratio when mixing may be freely selected, and the mass ratio of aliphatic epoxy resin to alicyclic epoxy resin may be about 2:8 to 8:2, or about 3:7 to 7:3, and is not limited to any specific mass ratio. In a preferable aspect, the thermosetting resin base used in encapsulating material 20 is a mixture in which the mass ratio of bisphenol A epoxy resin to alicyclic epoxy resin is 1:1 to 1:4.

The inorganic filler may be a metal oxide or a metal nitride, and examples thereof include fused silica, silica (silicon oxide), alumina, aluminum hydroxide, titania, zirconia, aluminum nitride, talc, clay, mica, and glass fiber, but they are not limited thereto. These inorganic fillers can increase the thermal conductivity of the encapsulating material 20 and reduce the thermal expansion coefficient. These inorganic fillers may be used alone, or two or more may be used as a mixture. The inorganic filler may be a microfiller, a nanofiller, or a mixture of two or more inorganic fillers of different particle sizes and/or types. In particular, it is preferable to use an inorganic filler with an average particle size of about 0.2 to 20 μm. The amount of inorganic filler added in the encapsulating material 20 is preferably 100 to 600 parts by mass, and even more preferably 200 to 400 parts by mass, when the total mass of the thermosetting resin base and the curing agent, which may optionally be contained, is 100 parts by mass. If the blending amount of inorganic filler is less than 100 parts by mass, the coefficient of thermal expansion of the encapsulating material 20 may increase, making it more prone to peeling and cracking. If the blending amount is greater than 600 parts by mass, the viscosity of the composition may increase and the extrusion moldability may be reduced.

The thermosetting resin composition constituting encapsulating material 20 may contain a curing agent as an optional component. The curing agent is not particularly limited as long as it can react with and cure the thermosetting resin base, preferably the epoxy resin base, and an acid anhydride-based curing agent is preferably used. Examples of the acid anhydride-based curing agent include aromatic acid anhydrides, specifically phthalic anhydride, pyromellitic anhydride, and trimellitic anhydride. Alternatively, these include cyclic aliphatic anhydrides, specifically tetrahydrophthalic anhydride, methyl tetrahydrophthalic anhydride, hexahydrophthalic anhydride, methyl hexahydrophthalic anhydride, and methyl nadic anhydride; and aliphatic acid anhydrides, specifically succinic anhydride, polyadipic anhydride, polysebacic anhydride, and polyazelaic anhydride. The blending amount of curing agent is preferably about 50 parts by mass or more and 170 parts by mass or less, and more preferably 80 parts by mass or more and 150 parts by mass or less per 100 parts by mass of the thermosetting resin (epoxy resin) base. When the blending amount of the curing agent is less than 50 parts by mass, the glass transition temperature may decrease due to insufficient cross-linking, and when it is more than 170 parts by mass, it may result in a decrease in moisture resistance, high heat deformation temperature, and heat resistance stability. When bisphenol A epoxy resin alone, or a mixture of bisphenol A epoxy resin and a high heat-resistant epoxy resin as exemplified above is used as the thermosetting resin base, it may be preferable not to use a curing agent, as it improves heat resistance. The blending ratio of the high heat-resistant epoxy resin may be, for example, 10% by mass or more and 50% by mass or less, and more preferably 10% by mass or more and 25% by mass or less, when the total mass of the thermosetting resin base is 100%. This range is preferable as it improves heat resistance and prevents thickening.

A curing accelerator can be further added to the thermosetting resin composition constituting the encapsulating material 20 as an optional component. As a curing accelerator, an imidazole or derivative thereof, a tertiary amine, a borate ester, a Lewis acid, an organometallic compound, a metal salt of an organic acid, or the like can be appropriately blended. The amount of curing accelerator added is preferably 0.01 parts by mass or more and 50 parts by mass or less, and more preferably 0.1 parts by mass or more and 20 parts by mass or less per 100 parts by mass of the thermosetting resin base.

The thermosetting resin composition constituting the encapsulating material 20 may also contain an optional additive as long as it does not impair its properties. Examples of additives include flame retardants, pigments to color the resin, and plasticizers and silicone elastomers to improve crack resistance, but they are not limited thereto. These optional components and the amounts added can be appropriately determined by those skilled in the art according to the specifications required for the semiconductor device and/or encapsulating material.

The encapsulating material 20 may have a one-layer configuration composed of one type of resin including the composition illustrated above, or it may have a configuration including two or more layers. A layer of thermoplastic resin or silicone rubber may be further included on top of one or more thermosetting resin layers.

The cross-sectional structure of a specific module is shown in FIG. 1 to describe the present invention, but the configuration of the semiconductor device is not limited to the illustrated form. For example, the conductive connecting member may be only one of a lead frame, wire or implant pin, or it may include two or more thereof. It may also be a caseless semiconductor device that does not include a case. Furthermore, it can also be a semiconductor device further including a printed board connected to the front electrode of the semiconductor element by, for example, an implant pin, in which the printed board is insulated and sealed.

To produce the semiconductor device, the semiconductor element 11 is bonded, for example, on the radiator plate 13 and the laminate substrate 12 by using the solder material according to the first embodiment. Next, the case 16 is attached and fixed to the radiator plate 13 using a resin or the like. Then, bonding of the lead frame 18 and wire bonding with the aluminum wire 14 are performed. Depending on the configuration of the semiconductor device, an implant pin and a printed board can be optionally bonded. Next, the thermosetting resin composition constituting the encapsulating material 20 is injected into the case 16 and heat cured. The step of heat curing can be, for example, two-stage curing, and when an epoxy resin is used as the thermosetting resin base, it is heated at 90 to 120° C. for 1 to 2 hours to obtain a semi-cured state. Then, the main curing can be carried out by further heating at 175 to 185° C. for 1 to 2 hours. However, it is not limited to a specific temperature or time and may not need to be two-stage curing. A caseless semiconductor device can be produced by bonding a laminate substrate and a semiconductor element by the solder material according to the first embodiment, attaching a conductive connecting member such as a lead frame or aluminum wire, then placing them in a mold and filling it with encapsulating material.

In the semiconductor device according to the third embodiment, a semiconductor element, a laminate substrate, or a cooling system is bonded by the solder material according to the first embodiment. This allows the obtaining of a device less prone to cracking and that is highly reliable.

### Examples

Hereinafter, the present invention will be described in more detail with reference to the Examples of the present invention. However, the present invention is not limited to the scope of the following Examples.

### Examples

### (1) Evaluation of Mechanical Properties of Solder Material

Samples in which 0 to 8% by mass of Cu was added to an alloy containing 6% by mass of Sb, 4% by mass of Ag, 0.25% by mass of Ni, and the remainder consisting of Sn and inevitable impurities, were produced to evaluate elongation at break, Young's modulus, and creep rupture elongation at 175° C. as their mechanical properties.

The stress-strain curve of the tensile test was obtained based on JIS Z2241: 2011 Metallic materials-Tensile testing, Young's modulus was calculated from the slope of the curve, and elongation at break (%) was calculated from the strain at break (when the stress becomes zero). The shape of the test piece is shown in FIG. 2A and the cross-sectional view of FIG. 2A at the X-X line is shown in FIG. 2B. In FIG. 2A, a dumbbell-shaped sample was used, in which the length L1 of the test piece was 12.0 mm, the length L2 of both ends was 3.9 mm, the diameter ø1 of both ends was 2 mm, the gauge length L3 was 2.4 mm, and the diameter ø2 was 1 mm. The tensile test was performed at a strain rate of 2.0×10⁻³ (1/s) and a temperature of 175° C. using a micro tensile testing machine (Saginomiya Seisakusho, Inc., model: LMH-207).

The creep curve was obtained based on JIS Z2271: 2010 Method of creep and creep rupture test for metallic materials, and the creep rupture elongation was obtained from the elongation at break. The test piece used was the same as for the tensile test. The creep rupture test was performed at a constant load of 7 N (8.92 MPa) and a temperature of 175° C., and the device used was the same as for the tensile test.

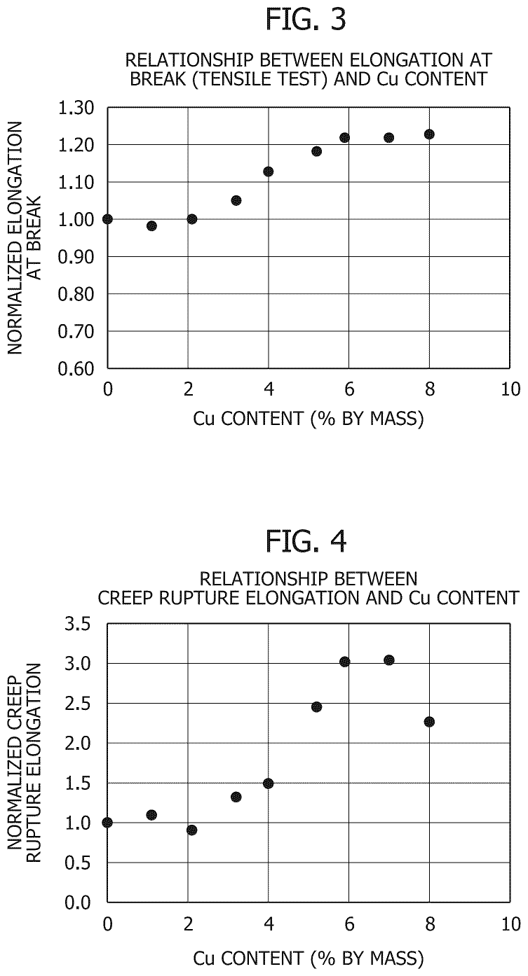

A relationship between the content of Cu in the solder material and the normalized elongation at break is shown in FIG. 3. The normalized elongation at break represents the relative value when the elongation at break at a Cu content of 0 is 1. FIG. 3 shows that the value of elongation at break is improved within a Cu content range of 3% by mass or more and 8% by mass or less.

A relationship between the content of Cu in the solder material and the normalized creep rupture elongation is shown in FIG. 4. The normalized creep rupture elongation represents the relative value when the creep rupture elongation at a Cu content of 0 is 1. FIG. 4 shows that with a Cu content of 3% by mass or more, the normalized creep rupture elongation was increased by 40% or more compared to when the Cu content was 0. In addition, the creep properties were maximum at a Cu content range of 5 to 7% by mass, and the normalized creep rupture elongation was twice or more that of when the Cu content was 0. While the creep properties were reduced when the content of Cu exceeded 7% by mass, the 40% or more increase in the normalized creep rupture elongation, as compared to when the Cu content was 0, was maintained as long as the Cu content was 8% by mass or less.

Varying the Cu content in the solder material from 0 to 8% by mass caused little to no change in the value of the normalized Young's modulus (graph not shown).

### (2) Evaluation of Reliability of Semiconductor Device

Solder material samples 1 to 18 were prepared with the compositions shown in Tables 1 and 2 below. A power semiconductor module was produced, which includes solder bonding layer 10 in which the solder material was melted, at the bonding portion of a Si semiconductor element as semiconductor element 11 and a laminate substrate including a first conductive plate 121 and second conductive plates 123a and b consisting of Cu as laminate substrate 12, as shown in FIG. 1. The bonding conditions were 260° C. to 290° C. and 100 to 160 seconds for the retention temperature and retention time under a N₂ reducing environment. The solder between the laminate substrate and the semiconductor element was applied using a metal mask with an aperture of 3.2 mm sq and a thickness of 200 μm. The paste solder used in the present Example was a common flux with rosin as the main component. The paste solder used was obtained by kneading this rosin-based flux and powdered solder with a particle size of 25 to 45 μm at a mass ratio of 1:1.

### Evaluation of TⱼP/C Capability

The reliability of the power semiconductor module was evaluated by Tⱼ power cycle capability (TⱼP/C capability). The power cycle test was performed at 75 to 150° C. (ΔTᵥⱼ of 75° C.), with one cycle consisting of 1 second of operation (current value set to reach 150° C.) and 9 to 15 seconds of pause (current value set to reach 75° C.). The number of cycles until the current or voltage exhibited abnormality was defined as the P/C capability. The evaluation criteria for P/C capability were A for 50k cycles or more, B for 40k cycles or more and 50k cycles or less, C for 25k cycles or more and less than 40k cycles, and D for less than 25k cycles.

### Evaluation of Wettability

Surface tension was measured using a Wilhelmy method wetting tester (Rhesca; SAT-5100, compliant with JIS Z 3198-4). This is a measurement method to determine the contact angle from the force applied to the perimeter around which the tip of a test piece is in contact with the liquid surface when the test piece is lifted after being immersed in a liquid. The test conditions were: immersion temperature of 270° C., 5×30×0.3 mm phosphorus deoxidized copper (C1220) was used as the test piece, and an appropriate amount of rosin-based flux was applied. The immersion rate was 5 mm/sec, the immersion depth 2 mm, and the immersion time 10 sec. The evaluation criteria were: A for a surface tension of less than 500 mN/m, B for 500 or more and less than 525 mN/m, and D for 525 mN/m or more. The surface tension of less than 500 mN/m of Evaluation A is the surface tension of Sn3.0Ag0.5Cu (solder material containing 3% by mass of Ag and 0.5% by mass of Cu, with the remainder consisting of Sn and inevitable impurities), which is an industrially common solder material. When the surface tension is less than 500 mN/m, defects such as voids are not observed in the solder bonding portion and its interface, which is preferable. A surface tension of 500 or more and less than 525 mN/m is not a problem in practice, but was rated as B as micro voids of about 1.0 mm may occur. On the other hand, when the surface tension is 525 mN/m or more (D), voids more easily occur in the bonding portion and its interface during module assembly (after solder bonding), and both void diameter and occurrence increase. When the surface tension is 525 mN/m or more, the maximum void diameter exceeds 1.5 mm when observed by ultrasonic testing (SAT), which is not preferable as it leads to a decrease in the reliability of the module.

The following Tables 1 and 2 show the compositions of the solder materials used as evaluation samples, the TⱼP/C capability and evaluation results of the power semiconductor modules, and the evaluation results of the wettability of the solder materials.

TABLE 1

| | Solder material | | | | | P/C | | |
|---|---|---|---|---|---|---|---|---|
| | composition (% by mass) | | | | | capability | | |
| Examples | Sn | Sb | Ag | Ni | Cu | (kcycle) | Rating | Wettability |
| Sample 1 | Remainder | 6.1 | 4.1 | 0.2 | 3.2 | 44 | B | A |
| Sample 2 | Remainder | 6.1 | 4.1 | 0.2 | 4.0 | 44 | B | A |
| Sample 3 | Remainder | 6.1 | 4.1 | 0.2 | 5.2 | 50 | A | A |
| Sample 4 | Remainder | 6.1 | 4.1 | 0.2 | 5.9 | 51 | A | A |
| Sample 5 | Remainder | 6.1 | 4.1 | 0.2 | 7.0 | 51 | A | A |
| Sample 6 | Remainder | 6.1 | 4.1 | 0.2 | 8.0 | 50 | A | A |
| Sample 7 | Remainder | 8.5 | 4.1 | 0.2 | 7.0 | 50 | A | A |
| Sample 8 | Remainder | 5.0 | 4.1 | 0.2 | 7.0 | 30 | C | A |
| Sample 9 | Remainder | 10.0 | 4.1 | 0.2 | 7.0 | 29 | C | A |
| Sample 10 | Remainder | 6.1 | 6.0 | 0.2 | 7.0 | 42 | B | B |
| Sample 11 | Remainder | 6.1 | 3.1 | 0.2 | 7.0 | 50 | A | A |
| Sample 12 | Remainder | 6.1 | 2.0 | 0.2 | 7.0 | 30 | C | A |

The results of Samples 1 to 6 showed that the lifetime of the semiconductor module was extended by a factor of about 1.5 or more when the Cu content was 3.2% by mass to 8% by mass. This is presumably due to the fact that the creep properties increased by a factor of 1.3 or more. In addition, when the Cu content was 5.2% by mass to 8% by mass, the service life of the semiconductor module was extended by a factor of about 1.7 or more. This is presumably due to the fact that the creep properties were improved by a factor of 2.0 or more.

On the other hand, in the power semiconductor module using the solder material of Sample 8 with reduced Sb for the bonding layer, cracks were observed in the Sn phase part of the solder bonding layer after the power cycle test. This is presumably the result of damage in the Sn portion due to the weakening of the effect of solid solution strengthening caused by the insufficient amount of Sb added, and as the amount of Sb was small, stress relaxation caused by Sn deformation occurred first. A higher content of Sb is believed to be preferable. The solder material of Sample 9 with increased Sb did not have satisfactory wettability, and voids were observed in some spots. In the power semiconductor module using the solder material of Sample 12 for the bonding layer, micro cracks of about 30 to 50 μm were observed mainly in the Sn phase of the solder bonding layer. An Ag content of 2% by mass or more is believed to be preferable as Ag₃Sn, which is densely dispersed in the solder structure, suppresses local deformation (deformation of the Sn phase). From Sample 10, it was confirmed that a high Ag content produced ultrasmall voids with a diameter of about 1.0 mm. These voids are not a problem in practice, but the presence of the voids is believed to have resulted in a slightly smaller P/C capability than in Sample 11.

From Table 1, it was confirmed that highly reliable power semiconductor modules with a P/C capability of 50k cycles or more are obtained by using solder materials containing Sb, Ag, Ni, and Cu in predetermined ranges to constitute the solder bonding layer. It is believed that within the predetermined composition ranges, the sliding that occurs due to the addition of Cu during the P/C test improves the stress relaxation effect of the solder material, which improves the capability.

TABLE 2

| | Solder material | | | | | P/C | | |
|---|---|---|---|---|---|---|---|---|
| Comparative | composition (% by mass) | | | | | capability | | |
| Examples | Sn | Sb | Ag | Ni | Cu | (kcycle) | Rating | Wettability |
| Sample 13 | Remainder | 8.0 | 3.0 | 0 | 0 | 13.5 | D | A |
| Sample 14 | Remainder | 6.1 | 4.1 | 0.2 | 0 | 20 | D | A |
| Sample 15 | Remainder | 6.1 | 4.1 | 0.2 | 1.1 | 21 | D | A |
| Sample 16 | Remainder | 6.1 | 4.1 | 0.2 | 2.1 | 23 | D | A |
| Sample 17 | Remainder | 6.1 | 1.1 | 0.2 | 7.0 | — | D | D |
| Sample 18 | Remainder | 6.1 | 7.1 | 0.2 | 7.0 | — | D | D |

In Table 2, “-” indicates that the P/C test was difficult to perform due to poor wettability, voids in the initial structure, and scattered solder balls (solidified solder). As shown in Table 2, in the power semiconductor modules using the solder materials of Samples 13 to 16 for the bonding layer, cracks were observed in the crystal grain boundaries of the Sn phase (β-Sn grain boundaries) of the solder bonding layer after the power cycle test. In Samples 13 and 14, it is believed that as Cu₆Sn₅ did not form in the structure, the improvement of the creep properties due to the improved sliding properties did not occur, whereas in Samples 15 and 16, Cu₆Sn₅ did form, but was sparsely distributed, and therefore the effect of Cu addition was not sufficiently exhibited. As a result, Samples 13 to 16 had cracks occurring at the β-Sn grain boundaries, thus reaching the end of their life. In Samples 17 and 18, the Ag content departed from the eutectic composition (3.5% by mass or more and 5.0% by mass or less), which reduced the wettability, and is believed to have resulted in the generation of voids and solder balls. In the solder bonding portion of Sample 18, AgSn compounds such as Ag₃Sn were formed in excess, resulting in a non-uniform structure.

The solder alloy of the present invention can be applied to general soldering parts. In particular, it can be suitably used in components that generate a large amount of heat, such as LED elements and power semiconductor devices such as power diodes. The solder alloy of the present invention has excellent elongation at break and creep properties (creep rupture elongation) at high temperatures, which improves the reliability of the solder bonding portion. In particular, an improvement in capability was observed in the P/C tests using an IGBT module. The increase in electrical resistance due to the generation of cracks, which is an issue during operation at high temperatures, can be eliminated by improving the elongation at break and the creep properties.

### REFERENCE SIGNS LIST

10 Bonding layer
11 Semiconductor element
12 Laminate substrate
121 First conductive plate
122 Insulating substrate
123a, 123b Second conductive plate
13 Radiator plate
14 Aluminum wire
15 External terminal
16 Case
17 Bonding layer
18 Lead frame
20 Encapsulating layer

1. A solder material comprising:
5.0% by mass or more and 10.0% by mass or less of Sb,
2.0% by mass or more and 6.0% by mass or less of Ag,
0.1% by mass or more and 0.5% by mass or less of Ni,
3.0% by mass or more and 8.0% by mass or less of Cu, and
the remainder consisting of Sn and inevitable impurities.

2. The solder material according to claim 1, comprising 4.5% by mass or more and 8.0% by mass or less of Cu.

3. The solder material according to claim 1, comprising 6.0% by mass or more and 8.5% by mass or less of Sb.

4. The solder material according to claim 2, comprising 6.0% by mass or more and 8.5% by mass or less of Sb.

5. The solder material according to claim 1, comprising 3.0% by mass or more and 6.0% by mass or less of Ag.

6. The solder material according to claim 2, comprising 3.0% by mass or more and 6.0% by mass or less of Ag.

7. The solder material according to claim 3, comprising 3.0% by mass or more and 6.0% by mass or less of Ag.

8. The solder material according to claim 1, used for bonding a semiconductor element.

9. A solder bonding portion, comprising a solder bonding layer in which the solder material according to claim 1 is melted, and a member to be bonded comprising a metal layer on a surface in contact with the solder bonding layer.

10. A semiconductor device, comprising a semiconductor element bonded on a laminate substrate, and a conductive connecting member bonded to the semiconductor element, wherein the device comprises the solder bonding portion according to claim 9 between the laminate substrate and the semiconductor element or between the semiconductor element and the conductive connecting member.

11. A semiconductor device, comprising a semiconductor element bonded on a laminate substrate, and a cooling system bonded to the opposite side of the laminate substrate from the side to which the semiconductor element is bonded, wherein the device comprises the solder bonding portion according to claim 9 between the laminate substrate and the cooling system.
